(19) United States
(12) Patent Application Publication
(10) Pub. No.: US 2022/0415624 A1
(43) Pub. Date: Dec. 29, 2022

(54) CARRIER RING TO PEDESTAL KINEMATIC MOUNT FOR SUBSTRATE PROCESSING TOOLS

(71) Applicant: Lam Research Corporation, Fremont, CA (US)

(72) Inventors: Nick Ray LINEBARGER, Jr., Beaverton, OR (US); Seshu NIMMALA, Beaverton, OR (US); Eric MADSEN, Sherwood, OR (US); Rigel Martin BRUENING, West Linn, OR (US)

(21) Appl. No.: 17/775,725

(22) PCT Filed: Nov. 18, 2020
(86) PCT No.: PCT/US2020/061002

§ 371 Date: May 10, 2022

Related U.S. Application Data
(60) Provisional application No. 62/940,654, filed on Nov. 26, 2019.

(51) Int. Cl. H01J 37/32; C23C 16/458; C23C 16/505; C23C 16/52

(52) U.S. Cl. CPC H01J 37/32715; H01J 37/32642; C23C 16/4585; C23C 16/505; C23C 16/52; H01J 2237/3321

(57) ABSTRACT

Various kinematic mounts used to mount a carrier ring carrying a substrate to a pedestal within a processing chamber. Each of the various kinematic mounts provide a smooth gliding action during mounting, reduce the generation of unwanted particles and prevent free-fall of the carrier ring to the pedestal.

### CROSS REFERENCE TO RELATED APPLICATIONS

This application claims priority of U.S. Provisional Patent Application No. 62/940,654 filed Nov. 26, 2019, and which is incorporated by reference herein for all purposes.

### FIELD OF THE INVENTION

The present application is directed to various kinematic mounts used to mount a carrier ring carrying a substrate to a pedestal within a processing chamber, and more particularly, to various kinematic mounts that each provide a smooth gliding action during mounting, reduce the generation of unwanted particles and prevent free-fall of the carrier ring to the pedestal.

### DESCRIPTION OF RELATED ART

Substrate processing tools, such as Chemical Vapor Deposition (CVD) tools or plasma etching tools, are known and commonly used for processing substrates, such as semiconductor wafers, flat panel displays and photovoltaic panels. Such tools, regardless of the type, all typically include a processing chamber, a pedestal within the processing chamber, and some type of mounting mechanism for mounting and aligning the substrate in position on the pedestal during processing.

One known mounting mechanism used for semiconductor wafer processing tools includes the combination of a ring with three pins spaced 120° apart and three recesses formed in the top surface of the pedestal, also spaced 120° apart. During a mounting operation, the ring is used to carry the substrate in the processing chamber, the pins of the ring are aligned with the recesses in the pedestal, and a mechanical force is then applied, forcing the pins into place (i.e., a final mounting position) within the recesses. There are a number of issues with the above-described design.

First, the pins are typically machined from aluminum, which is generally a soft material, particularly at the elevated temperatures (e.g., 250°-400° C.) commonly used in processing chambers. The pins are therefore prone to wear and losing their shape over time.

Second, the pedestal is often made of a much harder material, such as ceramic, which is difficult and costly to machine. With the pin and recesses made of disparate materials, machining the two to the same degree of precision and tolerance is difficult and expensive.

Third, the different geometric shapes and/or surfaces of the pins and the recesses also cause a number of issues during mounting. The recesses are typically machined to have a curved internal surface that gradually tapers to a flat vertical surface. With this arrangement, the opening gradually transitions from wide to narrow into the depth of the recess. The pins, on the other hand, are each machined to have a flat bottom. When a pin is inserted, unless perfectly aligned, the flat bottom strikes curved internal surface of the recess. With disparate surfaces contacting one another, excess friction prevents the pins from simply gliding into their final mounting position within the depth of the recesses by force of gravity. Instead, the aforementioned mechanical force is needed to force the pin into their final mounting position. When such a mechanical force is applied, the pins are essentially dragged or scraped across the curved internal surface of the recess, generating unwanted particles and other contaminants. In addition, a condition referred to as “free-fall” may occur if the external force suddenly overcomes the friction, causing the carrier ring to bang or slam into the pedestal. Such mechanical disturbances may cause misalignment issues, which at least in the semiconductor industry, can be catastrophic, resulting in unworkable integrated circuitry and lower yields.

Improved kinematic mount designs that provide a smooth gliding action during mounting, reduce the generation of unwanted particles and prevent free-fall, are therefore needed.

### SUMMARY

The present application is directed to various kinematic mounts used to mount a carrier ring carrying a substrate to a pedestal within a processing chamber. Each of the various kinematic mounts provide a smooth gliding action during mounting, reduce the generation of unwanted particles and prevent free-fall of the carrier ring to the pedestal.

More particularly the present application is directed to an apparatus including a processing chamber, a pedestal having a surface for supporting a substrate within the processing chamber, a carrier ring for carrying the substrate within the processing chamber and a kinematic mount for mounting the carrier ring onto the pedestal and for aligning the substrate onto the surface of the pedestal. The kinematic mount includes a parabolic-shaped pin having a curved surface entry profile and a recess having substantially vertical sidewalls and also potentially curved internal surface walls as well. When the pin is aligned with and inserted into the recess of the kinematic mount, the initial point of contact between the pin and the recess is either with the vertical sidewalls or the curved internal surface wall. In either case, just gravitational forces are typically sufficient to overcome frictional forces, allowing the pin to glide into a mounting position within the recess, preferably without the need to apply an external mechanical force.

In one alternative embodiment, the pin is provided on the carrier ring and the recess is provided on the pedestal. In a variation of this embodiment, the carrier ring includes three pins spaced 120° apart and the pedestal includes three recesses also each spaced 120° apart.

In another alternative embodiment, the pin is provided on the substrate and the recess is provided on the carrier ring. In a variation of this embodiment, the substrate includes three pins spaced 120° apart and the carrier ring includes three recesses also each spaced 120° apart.

In yet other embodiments, the recess may include a number of different shapes, including, but not limited to, horseshoe or racetrack. In yet other embodiments, the recess may be press-fit, snap-fit or otherwise kinematically fastened without the need of other fastening components.

The various kinematic mounts, regardless of the embodiment, each have at least one pin with an optimized geometry that results in at least the following advantages:
(a) A smooth, sliding action that allows the pin to glide into a final mounting position within recesses without the need of an external force;
(b) Reduces excess friction between pin and recess surfaces, resulting in the generation fewer particles and other contaminants, and
(c) Prevents “free-fall” of the carrier ring to the pedestal during mounting, mitigating mechanical disturbances that may also cause misalignment issues.

### BRIEF DESCRIPTION OF THE DRAWINGS

The present application and the advantages thereof, may best be understood by reference to the following description taken in conjunction with the accompanying drawings in which:

FIG. 1 is a diagram of an exemplary substrate processing tool in accordance with a non-exclusive embodiment of the present invention.

FIG. 2 is a block diagram of a system controller used for controlling the substrate processing tool in accordance with a non-exclusive embodiment of the invention.

FIG. 3A though FIG. 3C are various views of a carrier ring and pedestal in accordance with non-exclusive embodiments of the invention.

FIG. 4 is a diagram illustrating a range of carrier ring pin geometries in accordance non-exclusive embodiments of the invention.

FIG. 5 illustrates a pin-recess design for a kinematic mount in accordance with a first embodiment of the present invention.

FIGS. 6A through 6C illustrate a second recess design for a kinematic mount in accordance with a second embodiment of the present invention.

FIG. 7 illustrates a third recess design for a kinematic mount in accordance with a third embodiment of the present invention.

FIGS. 8A and 8B are enlarged views of an exemplary pin contacting a substantially vertical sidewall or a sloped/curved sidewall of a recess of a kinematic mount in accordance with the present invention.

In the drawings, like reference numerals are sometimes used to designate like structural elements. It should also be appreciated that the depictions in the Figures are diagrammatic and not necessarily to scale.

### DETAILED DESCRIPTION

The present application will now be described in detail with reference to a few non-exclusive embodiments thereof as illustrated in the accompanying drawings. In the following description, numerous specific details are set forth in order to provide a thorough understanding of the present disclosure. It will be apparent, however, to one skilled in the art, that the present discloser may be practiced without some or all of these specific details. In other instances, well known process steps and/or structures have not been described in detail in order to not unnecessarily obscure the present disclosure.

### Exemplary PECVD Tool

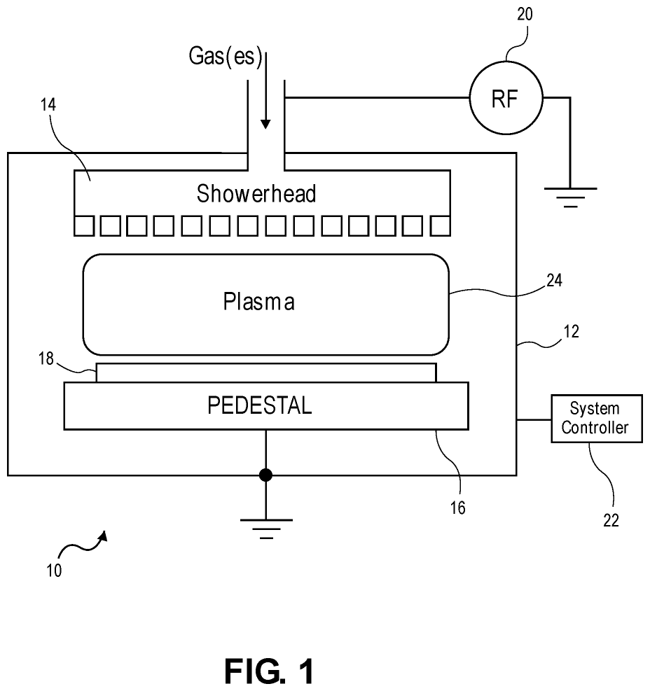

Referring to FIG. 1, a diagram of an exemplary substrate processing tool 10 in accordance with a non-exclusive embodiment of the present invention is illustrated. In this particular embodiment as described below, the tool is a Plasma Enhanced (PECVD) tool.

It should be understood that the description below of the PECVD tool 10 is merely exemplary and that the various kinematic mount designs as described herein may be used in any type of substrate processing tool, including but not limited to any Chemical Vapor Deposition (CVD) tool, Low Pressure CVD (LPCVD) tools, High Vacuum CVD (HVCVD) tools, Remote Plasma Enhanced CVD (RPECVD) tools, Atomic Layer CVD (ALCVD) or sometimes referred to as Atomic Layer Deposition (ALD) tools, etc. Furthermore, that the various kinematic mount designs as described herein may also be used in other types as tools as well, such as wet or dry etching tools. It is also noted that the term substrate as used herein should be broadly construed to include any type of work piece that may be processed within a substrate processing tool, such as but not limited to, semiconductor wafers, flat panel displays, photoelectric panels, etc.

The PECVD tool 10 includes a processing chamber 12, a shower head 14, a pedestal 16 for supporting and positioning a substrate 18 to be processed, Radio Frequency (RF) generator 20, and a system controller 22.

During operation, reactant gas(es) is/are supplied into the process chamber 12 through the shower head 14. Within the shower head 14, the gas(es) is/are distributed via one or more plenums (not illustrated) into the chamber 12, in the general area above the surface of the substrate 18 to be processed. An RF potential, generated by the RF generator 20, is applied to an electrode (not illustrated) on the shower head 14 and/or an electrode (also not shown) on the pedestal 16. The RF potential generates plasma 24 within the processing chamber 12. Within the plasma 24, energized electrons ionize or dissociate (i.e., “crack”) from the reactant gas(es), creating chemically reactive radicals. As these radicals react, they deposit and form thin films on the semiconductor substrate 18.

In various alternative embodiments, the plasma 24 within the chamber 12 can be sourced either capacitively or inductively. In yet further embodiments, the RF generator 20 may be a single RF generator or multiple RF generators capable of generating high, medium and/or low RF frequencies. For example, in the case of high frequencies, the RF generator 20 may generate frequencies ranging from 2-100 MHz and preferably 13.56 MHz or 27 MHz. When low frequencies are generated, the range is 50 KHz to 2 MHz, and preferably 350 to 600 KHz. In yet other embodiments, the tool 10 may be an etching tool that is used to etch or remove material from the substrate 18.

### System Controller

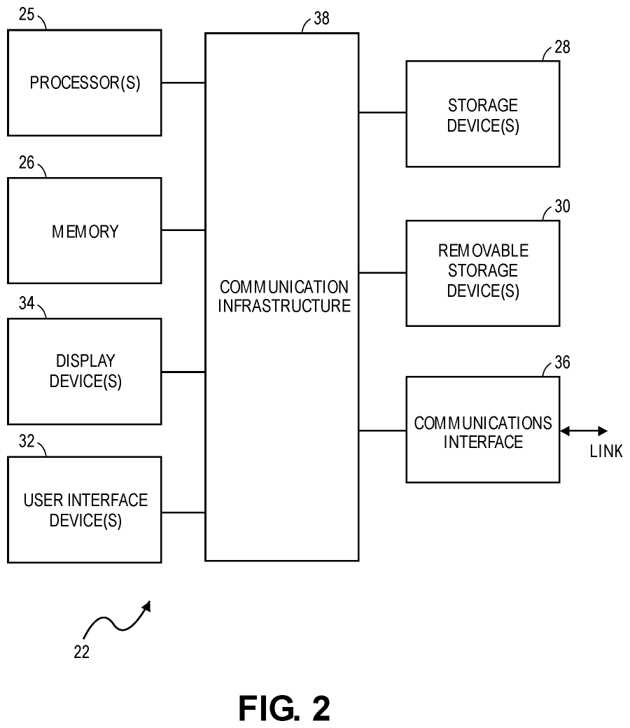

Referring to FIG. 2, a block diagram of the system controller 22 in accordance with a non-exclusive embodiment of the invention is shown. The system controller 22, which generally controls the overall operation of the PEALD tool 10, includes one or more processor(s) 25, memory 26, one or more storage devices 28, one or more removable storage device(s) 30, one or more user interface device(s) 32, one or more display device(s) 34, a communication interface 36 and a communication infrastructure 38.

The processor(s) 25 may be implemented in a number of different forms ranging from one or more integrated circuits, printed circuit boards, handheld computing devices, personal computers, work stations, servers, super computers, a network of computers, any one of which may include one or multiple processors.

The memory 26 is provided as system memory and is used for a variety of reasons, including storing firmware, code, executable instructions and/or other software executed by the one or more of the processors 25. The memory 26 can also operate as operable memory storing computational data and the like during execution of such code, firmware, software, etc.

In various embodiments, the memory 26 may be implemented in a numbers of ways, including registers, cache memory, main memory, Random Access Memory (RAM), Read Only Memory (ROM), transient, non-transient or persistent memory, solid state memory, spinning disk memory, direct attached storage, network attached storage, one or more a storage disk arrays, optical storage devices, or a combination thereof. Such storage devices not only store firmware, code, executable instructions and/or other software, but are typically accessed and used by the processor(s) 25 during operation and control of the tool 10.

Similarly, the storage device 28 can be used for storing system data and may be implemented using a variety of different embodiments such as transient, non-transient or persistent, solid state memory, spinning disk memory, direct attached storage, network attached storage, one or more a storage disk arrays, optical storage devices, or a combination thereof.

Removable storage devices 30 may include embodiments such as removable storage disks, optical disks, thumb drives, memory sticks, USB sticks and the like.

The user interface device(s) 32 include any type of device that enables interaction with the system controller 22 and/or the tool 10. Such devices 32 may include keyboards, touch screens, pointers, mice, etc.

The display device(s) 34 can be any device capable of displaying information, such as a flat panel display, CRT, printers, etc.

The communication interface 36 allows software and data to be transferred between the system controller 22 and external devices via a link. The link is arranged to carry signals between the processor 22 and other external devices such as another computer, a network, other tools, etc. The link may be implemented using an electric wire or cable, fiber optics, a phone line, a cellular phone link, a radio frequency link, and/or other communication channels.

The communications infrastructure 38 allows all the above-listed sub-components of the processor 22 to communicate with one another. In various embodiments, the communications infrastructure 38 may be a communications bus, cross-over bar, or network and may be implemented using cable wiring, fiber optics, wirelessly, or a combination thereof.

As used herein, the term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals.

In certain embodiments, the system controller 22, running or executing system software or code, controls all or at least most of the activities of the tool 10 for implementing some or all of the processes as described herein, including but not limited to such activities as controlling robotic operations such as removing a processed substrate 18 from the processing chamber 12, insertion of a new substrate 18 for processing into the processing chamber 12, and mounting the new substrate onto the pedestal 18 as described in detail herein.

The system controller 22 is also generally responsible for controlling processing operations within the processing chamber 12 after a substrate 18 has been clamped to the pedestal 16. Such operation generally involve flow rates of reactants, concentrations and temperatures within the process chamber 12, frequency and power of the RF generator 20, temperature control of the substrate via heaters or coolers embedded in the pedestal 16, pressure within the processing chamber 12, timing of purging the processing chamber, etc.

### Kinematic Mount

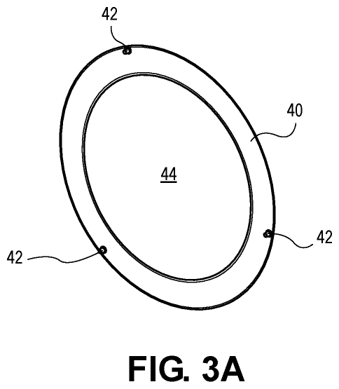

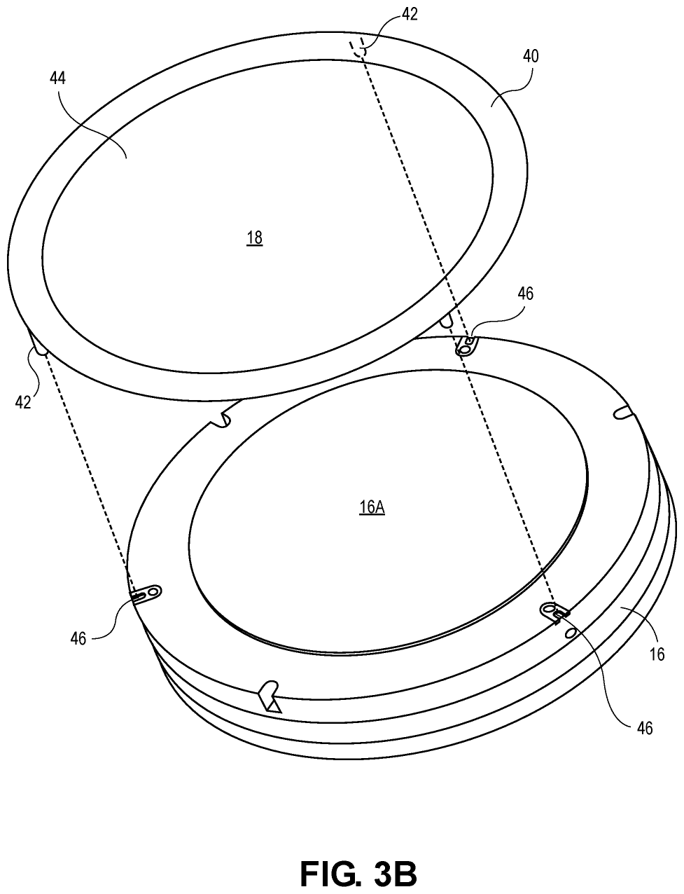

Referring to FIG. 3A though FIG. 3C, various views of a carrier ring 40 and/or the pedestal 16 are illustrated.

As illustrated in FIG. 3A, the carrier ring 40 with three pins 42, each spaced 120° apart, is shown. The center region 44 of the carrier ring 40 is open, meaning when the carrier ring 40 is used to align and mount a substrate 18 onto the pedestal 16, the active surface of the substrate 18 remains substantially exposed within the processing chamber 12.

In FIG. 3B, the carrier ring 40, carrying a substrate 18, is positioned above a top surface 16A of the pedestal 16. The carrier ring 40 is rotated as needed so that the three pins 42 are aligned with three recesses 46 that are formed in the top surface 16A of the pedestal 16. As the carrier ring 40 is lowered into place, and the three pins 42 are inserted into the recesses 46, the substrate 18 and carrier ring 40 are aligned and mounted onto the surface 16A of the pedestal 16.

As illustrated in FIG. 3C, a close-up view of one of the pins 42 on the mounting ring 40 is illustrated. As described in more detail below, the pins 42 have an optimized geometry, or range of optimized geometries, that results in a smooth, gliding action, when inserted into and contacting the internal curved walls of the corresponding recesses 46. Such a gliding action offers a number of advantages, including (a) allowing the pins 42 to smoothly glide into a final mounting position within the recess 46 just by gravitational force, eliminating the need for an external mechanical force to push the pins into place, (b) reduced friction, which eliminates or mitigates particle generation and (c) prevents or mitigates “free-fall”, which may cause substrate misalignment issues.

### Pin Geometries

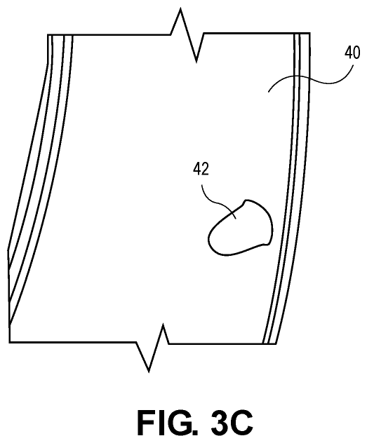

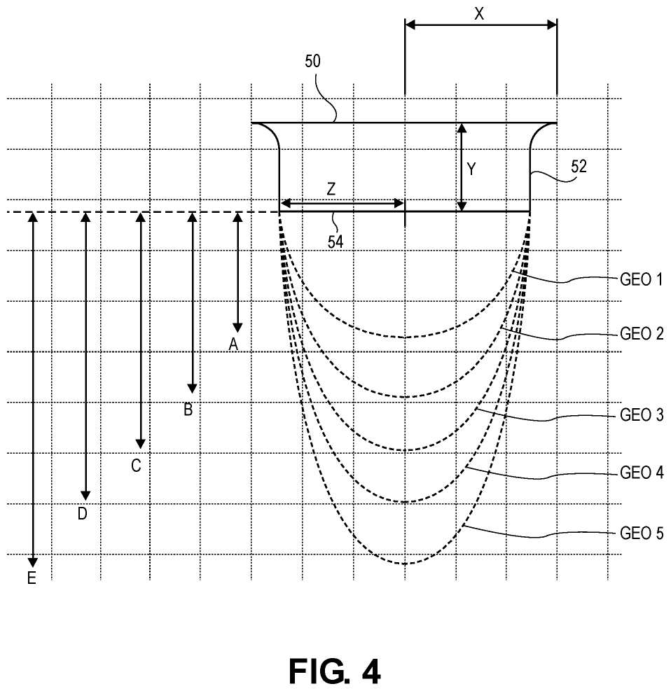

Referring to FIG. 4, a diagram illustrating a range of geometries of the pins 42 in accordance non-exclusive embodiments of the invention is illustrated. In particular, five (5) specific pin geometries are shown and labeled “Geo 1” through “Geo 5”. In each case, the pin geometries Geo 1 through Geo 5 are parabolic in shape.

Each of the pin geometries share a number of common characteristics, including:
(i) A base 50 having a radius in the particular embodiments shown of X inches. The base 50 defines where the pin 42 attaches to another object. As noted above, the other object can be the carrier ring 40, or alternatively as described in another embodiment below, also the pedestal 16. In various embodiments, the value of X may vary from 0.01 to 0.2, depending on the configuration of the pin 42 and/or the other object that the pin is attached to;
(ii) An extension portion 52 having a height of Y inches. The overall length of the pin 42 is defined by the extension portion plus an insertion length dimension provided in FIG. 4 for each of the Geo 1 (A) through Geo 5 (E). In various embodiments, the insertion length dimension can range from 0.1 inches or less to 0.25 inches or more; and

A second radius 54 defines the radius Z of the portion of the pin that is inserted into the recess 46. In the embodiment shown in FIG. 4, the value of Z can be the same or different for each Geo 1 (A) through Geo 5 (E). Alternatively, the value of Z may vary for each Geo 1 (A) through Geo 5 (E). In various embodiments, the value of Z may range from 0.1 to 0.3 inches, again depending on the configuration of the pin 42.

The range of above-defined geometries provides advantages over current known flat bottom pin designs. With prior pins, the initial contact is typically a flat surface hitting a curved surface within the recess. The frictional forces between the disparate surfaces are ordinarily too high for gravitational forces alone to allow the pins to simply fall into their final mounting position. As a result, an external mechanical forced is typically required to force the pins into a final mounting position within the depth of the recesses. As noted above, the use of such external forces leads to particle generation due to excess friction as well as mechanical disturbances.

Each of the geometries (Geo 1 through Geo 5) of the pins 42 as illustrated, on the other hand, define a parabolic-shaped entry profile having a curved surface. As a result, the initial contact between the pins 42 and the internal walls of the recesses 46 is either (i) a curved surface of the pin 42 contacting a substantially vertical sidewall surface of the recess 46 or one of two curved surfaces interacting with one another or (ii) the curved surface of the pin 42 contacting another curved surface of the recess 46. With at least one curved surface, there is less friction at the point of contact. As a result, gravitational forces alone are typically adequate to allow the pins 42 to smoothly glide into their final mounting position within the recesses 46. Note, that although the use of no external force may generally be preferred, the use of such an external force is not precluded from the scope of the present invention. On the contrary, any of the kinematic mounts as described herein can be used with an external force if needed or otherwise desired.

The curved entry profile of the pins 42, therefore, provides several advantages, including (a) reduces friction, eliminating or reducing particle generation, (b) eliminates a need in most situations to apply an external force to fully insert the pins 42 in to a final mounting position within the recesses 46, (c) provides a smooth gliding interaction that allows the pins to slip into the final mounting position by just gravitation forces and (d) mitigates or eliminates mechanical disturbances.

The individual geometries Geo 1 through Geo 5 demonstrated different operational characteristics as measured based on a finite analysis. All five geometries exhibited motion due to gravity alone overcoming friction. As a result, all five geometries provide a smooth motion upon insertion into a recess 46. Furthermore, the geometries with a steeper curve (e.g. Geo 3, Geo 4 and Geo 5, with Geo 5 being steepest) exhibit less frictional forces compared to those with a more gradual curve (e.g., Geo 1 and Geo 2). The steeper curved geometries thus resulted in a reduced contact time relative to the more gradual curved geometries. Thus, as a general rule, the pin geometries having a steeper curve provide the advantages of less friction, less contact time and a smoother gliding operation, all of which equates to less particle generation and less mechanical disturbances including free-fall. It is noted, however, that pins with extremely steep curves may not always be desirable. With extremely steep surfaces, pins may exhibit very high contact stresses, and therefore, should typically be avoided.

It is noted that the dimensions provided herein for the pin 42 are merely exemplary. Any of the dimensions, 50, 52, and 54 may all widely vary in radius and/or height. Furthermore, the insertion length and/or slope of the curve of the pins 42 may also widely vary from one application to the next. For example, the pins 42 may have a radius X, a radius Z a height Y and an insertion length (A) through (E) that is either smaller or larger than provided herein. Thus, the specific examples and/or dimensions as provided herein should be considered as illustrative, but not limiting in any regard. On the contrary, the dimensions and radiuses of the pins 42 may be smaller or larger and/or shorter or longer than mentioned herein and may widely vary from one tool to the next.

### Pin-Recess Embodiments

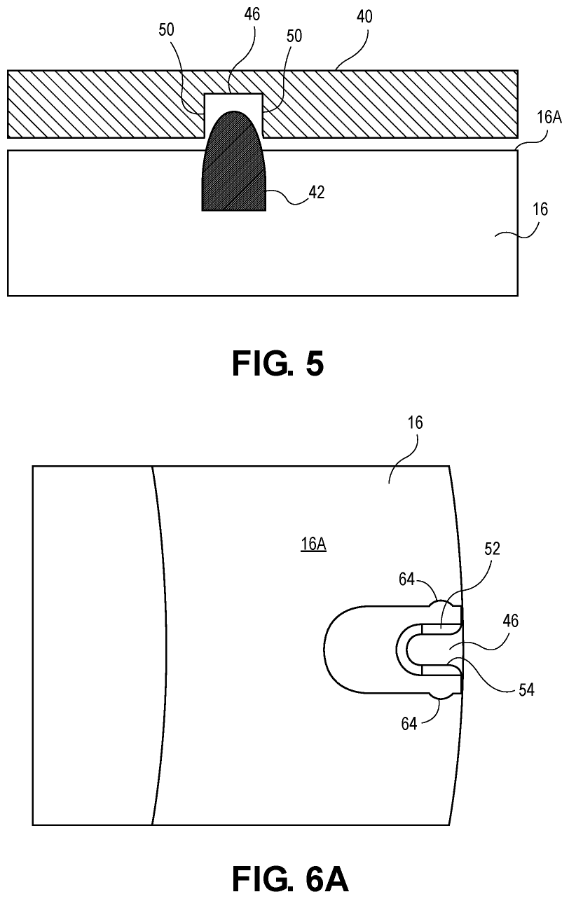

FIG. 5 illustrates a first pin-recess design for a kinematic mount in accordance with a first embodiment. With this embodiment, the pin 42 is press-fit, snap-fit or otherwise embedded into the pedestal 16 and protrudes upward from the surface 16A. The carrier ring 40 includes, in the particular embodiment shown, a square-shaped recess 46 with substantially vertical sidewalls 50. It is also noted that with this embodiment, the surface of the carrier ring 40, opposed to where the pin 42 is inserted, is covered, which prevents plasma and/or particles in the processing chamber from entering into the recess 46. With this embodiment, the carrier ring 40 is aligned so that the recesses 46 are aligned with the pins 42 in the pedestal 16. The carrier ring 40 is then lowered into place. If two are not perfectly aligned, a curved surface of parabolic-shaped pin 42 will typically first contact one of the vertical sidewalls 50 of the recess. With the curved surface of the pin 42, there is less friction compared to a pin with a flat contact surface, and as a result, the ring 40 will typically glide into place.

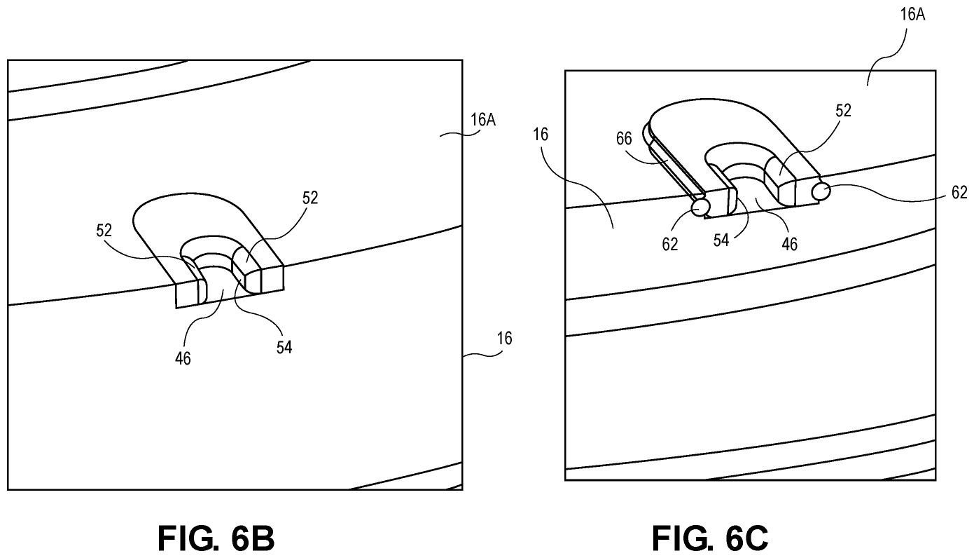

FIGS. 6A and 6B illustrates another design of a recess 46 of another kinematic mount in accordance with a second embodiment. In this embodiment, the recess 46 is horse-shoe shaped, is provided at the edge or periphery of the pedestal 16, and is either press-fit, snapped fit or slid into place via the side of the pedestal and flush with the top surface 16A.

The recess 46, as best illustrated in FIG. 6B, includes curved or sloped sidewalls 52 that gradually transition to vertical sidewall surfaces 54. With this arrangement, the curved surface of the parabolic shaped pin 42 will initially contact either (i) the vertical sidewall surfaces 54 if the two are near perfectly aligned or (ii) the curved surface 52 if the two are slightly mis-aligned. In either case, the curved surface of the pin 42 reduces surface friction, allowing the pin 42 to slide or glide into place within the recess 46.

In a variation of this embodiment, as shown in FIG. 6C, ceramic or metal balls 62 or the like may be used to lock the recess 46 into place within the bulk of the pedestal 16. Also notches 64 (FIG. 6A) and/or or grooves 66 (FIG. 6C) may be used to snap or press fit the recess 46 into place within the bulk of the pedestal 16. When notches 64 and/or grooves are used to lock the recess 46 in place, the pedestal 16 is modified to include mating features to allow the recesses 46 to be press and/or snap fitted into place.

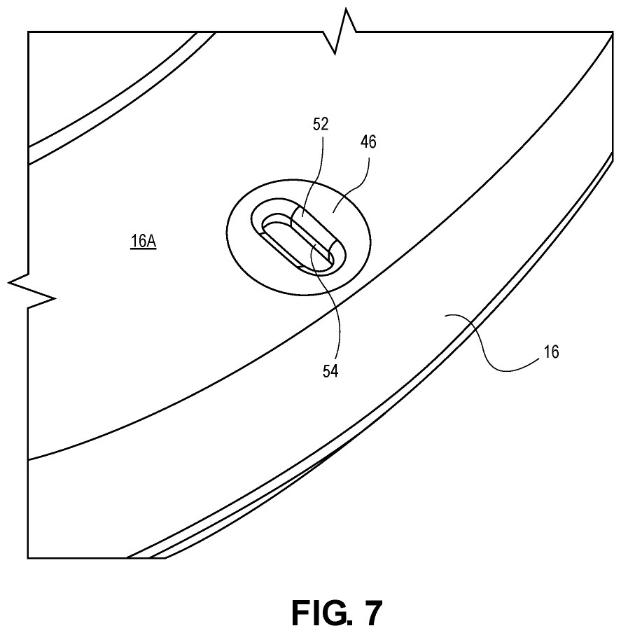

FIG. 7 illustrates another recess design in accordance with a third embodiment. In this case, the recess 46 is race-track shaped and is press-fit and/or snap-fit into the top surface 16A of the pedestal 16. Like the embodiments shown in FIG. 6A-FIG. 6C, the race-track shaped recess 46 includes internal surfaces 52 and 54 and operates in a manner similar to that described above upon insertion of a pin 42.

In each of the embodiments illustrated in FIGS. 5, 6A-6C and 7, only a single pin-recess pair is illustrated for the sake of simplicity. It should be understood that with each embodiment, a total of three pin-recess pairs are typically used, with each pair spaced 120° apart. It should be understood, however, that any number of pin-recess pairs may be used, including fewer or more than three. The present invention should therefore not be limited to using any specific number of pin-pairs.

It is further noted that at least the embodiments of FIGS. 5, 6A-6C and 7 are kinematic designs, meaning they are self-fastened to the pedestal without the need of other fastening components, such as screws, bolts and the like.

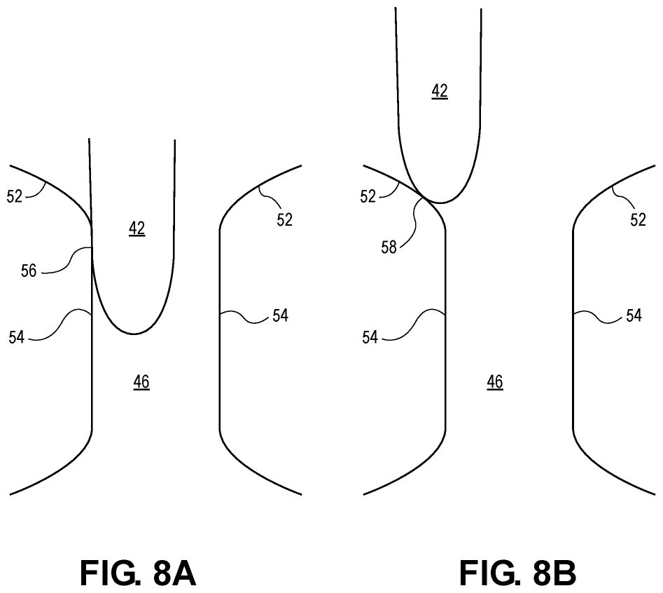

As noted above, during a mounting operation, carrier ring 40 is rotated so that the pins 42 are aligned with the recesses 46. The Carrier ring 40 is then lowered into position. The location of the first contact of the pins 42 to the internal sidewalls of the recess 46 may vary, depending on the level of precision of the alignment. If perfectly aligned, the pins 42 will be received into the recesses 46 with minimal to no contact with the internal sidewalls of the recesses 46. On the other hand even if there is a slight degree of misalignment, the first point of contact of the pins 42 is likely to be with an internal sidewall of the recess 42. FIG. 8A and FIG. 8B depict varying degrees of such a scenario.

Referring to FIGS. 8A and 8B, enlarged views of a parabolic-shaped pin 42 contacting a substantially vertical sidewall 54 and a sloped/curved sidewall 52 of a recess 46 of any of the kinematic mounts depicted in FIGS. 6A-6C or FIG. 7 are illustrated.

In FIG. 8A, the pin 42 is slightly out of alignment with the recess 46. As a result, the initial contact 56 of the pin 42 within the recess 46 is along one of the vertical sidewalls 54 of the recess 46.

In FIG. 8B, on the other hand, the alignment between the pin 42 and the recess is offset by a larger degree. As a result, the initial contact point 58 of the pin 42 within the recess 46 is on a sloped surface 52.

With either scenario of FIG. 8A or FIG. 8B, a curved surface of the parabolic shaped pin 42 reduces friction at the point of contact. In either case, just gravitational forces are typically sufficient to overcome frictional forces, preferably without the need to apply an external mechanical force. As a result, (a) a smooth gliding action will allow the pin 42 to slide into place within the recess 46, (b) particle generation is reduced due to less friction between the two surfaces and (c) the smooth, gliding action prevents “free-fall” of the carrier ring 40 to the pedestal 16, reducing mechanical disturbances.

It is noted that although the discussion above is specific to having the pins 42 located on the carrier ring 40 and the recesses 46 on the pedestal 16, the same concepts apply with the opposing arrangement. In other words for embodiments where the pins 42 are located on the pedestal 16 and the recesses 46 on the ring 40 (e.g., FIG. 5), similar principles discuss above apply. That is, a curved surface of the parabolic shaped pin 42 will first contact an internal sidewall of the recess, which may be either substantially vertical or sloped, to facilitate the smooth, gliding action of positioning the pin into its final insertion position.

Although only a few embodiments have been described in detail, it should be appreciated that the present application may be implemented in many other forms without departing from the spirit or scope of the disclosure provided herein. Therefore, the present embodiments should be considered illustrative and not restrictive and is not to be limited to the details given herein, but may be modified within the scope and equivalents of the appended claims.

What is claimed is:

1. An apparatus, comprising:
a processing chamber;
a pedestal having a surface for supporting a substrate within the processing chamber;
a carrier ring for carrying the substrate within the processing chamber; and
a kinematic mount for mounting the carrier ring onto the pedestal and for aligning the substrate onto the surface of the pedestal, the kinematic mount including:
a recess having a internal surface, the recess provided either within the surface of the pedestal or the carrier ring; and
a pin arranged to be inserted into the recess when mounting the carrier ring onto the pedestal, the pin arranged to have a curved surface that makes contact with the internal surface of the recess when the pin is inserted into the recess.

2. The apparatus of claim 1, wherein the curved surface of the pin and the internal surface of the recess interact with respect to one another such that gravitational forces are sufficient to overcome frictional forces, allowing the pin to glide into a mounting position within the recess.

3. The apparatus of claim 1, wherein the curved surface of the pin and the internal surface of the recess interact with respect to one another to guide the pin into a mounting position within the recess.

4. The apparatus of claim 1, wherein the curved surface of the pin and the internal surface of the recess interact with respect to one another such that no external mechanical force is needed to position the pin to a mounting position within the recess.

5. The apparatus of claim 1, wherein the curved surface of the pin defines a slope with respect to the internal surface of the recess such gravitational forces are sufficient to overcome frictional forces, allowing the pin to glide into a mounting position within the recess.

6. The apparatus of claim 1, wherein the pin is provided on the carrier ring and the recess is provided on the pedestal.

7. The apparatus of claim 5, further comprising three pins on the carrier ring and three recesses on the pedestal, wherein the three pins and the three recesses are each spaced 120° apart respectively.

8. The apparatus of claim 1, wherein the pin is provided on the pedestal and the recess is provided on the carrier ring.

9. The apparatus of claim 7, further comprising three pins on the pedestal and three recesses on the carrier ring, wherein the three pins and the three recesses are each spaced 120° apart respectively.

10. The apparatus of claim 7, wherein a surface of the recess, opposed to where the pin is inserted, is covered to prevent plasma and/or particles from entering into the recess.

11. The apparatus of claim 1, wherein the recess is horse-shoe shaped.

12. The apparatus of claim 1, wherein the recess is race-track shaped.

13. The apparatus of claim 1, wherein the recess is press-fit into the pedestal.

14. The apparatus of claim 1, wherein the recess is snap-fit into the pedestal.

15. The apparatus of claim 1, wherein the recess is kinematically fastened to the pedestal without the need of other fastening components.

16. The apparatus of claim 1, wherein the pin is made from Aluminum Oxide (AL₂O₃).

17. The apparatus of claim 1, wherein the pedestal is made from ceramic.

18. The apparatus of claim 1, wherein the pin has an insertion length ranging from 0.05 to 0.3 inches.

19. The apparatus of claim 1, wherein the pin has a radius ranging from 0.1 to 0.3 inches.

20. The apparatus of claim 1, wherein the pin is parabolic in shape.

21. The apparatus of claim 1, wherein the internal surface of the recess is characterized by one of the following:
(a) substantially vertical sidewalls; or
(b) internally curved walls that taper to the substantially vertical sidewalls.

22. A kinematic mount that is used to mount a substrate carrier ring to a pedestal within a processing chamber of a substrate processing tool, the kinematic mount including a recess that is designed to be press-fit or snap-fit into a surface of the pedestal.

23. The kinematic mount of claim 22, wherein the recess is horse-shoe shaped.

24. The kinematic mount of claim 22, wherein the recess is race-track shaped.

25. The kinematic mount of claim 22, wherein the recess defines internal surface walls that are substantially vertical.

26. The kinematic mount of claim 22, wherein the recess further defines internally sloped sidewalls that taper to the internal surface walls that are substantially vertical.

27. The kinematic mount of claim 22, further comprises one of the following to facilitate the snap or press fitting of the recess into the surface of the pedestal:
(a) a notch
(b) a groove; or
(c) both (a) and (b).

28. The kinematic mount of claim 22, wherein the recess is further arranged to slide into a sidewall of the pedestal so that the recess is provided within the surface of the pedestal.

29. The kinematic mount of claim 22, wherein the recess is further arranged to receive a parabolic shaped pin.
